(19) United States
(12) Patent Application Publication
(10) Pub. No.: US 2011/0278613 A1
(43) Pub. Date: Nov. 17, 2011

(54) LIGHT EMITTING DIODE AND MANUFACTURING METHOD THEREOF

(75) Inventors: Po-Min Tu, Hukou (TW); Shih-Cheng Huang, Hukou (TW); Chia-Hung Huang, Hukou (TW); Shun-Kuei Yang, Hukou (TW)

(73) Assignee: ADVANCED OPTOELECTRONIC TECHNOLOGY, INC., Hsinchu Hsien (TW)

(21) Appl. No.: 12/975,229

(22) Filed: Dec. 21, 2010

(30) Foreign Application Priority Data
May 14, 2010 (CN) 201010172770.6

(51) Int. Cl. H01L 33/60; H01L 33/12

(52) U.S. Cl. 257/98; 438/22; 257/E33.072; 257/E33.001

(57) ABSTRACT

A light emitting diode includes a substrate, a buffer layer on the substrate, a patterned layer having a first reflective index on the buffer layer, a semiconductor layer having a second reflective index on the patterned layer, and an illumination structure on the semiconductor layer. A method for manufacturing the light emitting diode is also provided.

### BACKGROUND

1. Technical Field

The disclosure relates to light emitting diodes, and more particularly to a light emitting diode with high light extraction efficiency and fabrication method thereof.

2. Description of the Related Art

Semiconductor materials of nitride compound are commonly applied in the light emitting diode field. Such structure often includes a substrate, a gallium nitride buffer layer formed on the substrate, an aluminum gallium nitride bound layer formed on the gallium nitride buffer layer, and an illumination structure formed on the aluminum gallium nitride bound layer. The epitaxial quality of the light emitting diode may exhibit defects when the surface of the aluminum gallium nitride bound layer cracks from the stress of the aluminum gallium nitride bound layer. Additionally, emitted light is easily absorbed by the gallium nitride buffer layer, inhibiting the total light extraction efficiency of the light emitting diode.

Therefore, it is desirable to provide a light emitting diode structure which can overcome the described limitations.

### BRIEF DESCRIPTION OF THE DRAWINGS

FIG. 1 is a cross section of the light emitting diode of the present disclosure.

FIG. 2 is a cross section of a substrate to a patterned layer of the light emitting diode in FIG. 1.

FIG. 3 is a top view of the patterned layer in FIG. 2.

FIG. 4 is a flow chart for manufacturing the light emitting diode.

### DETAILED DESCRIPTION

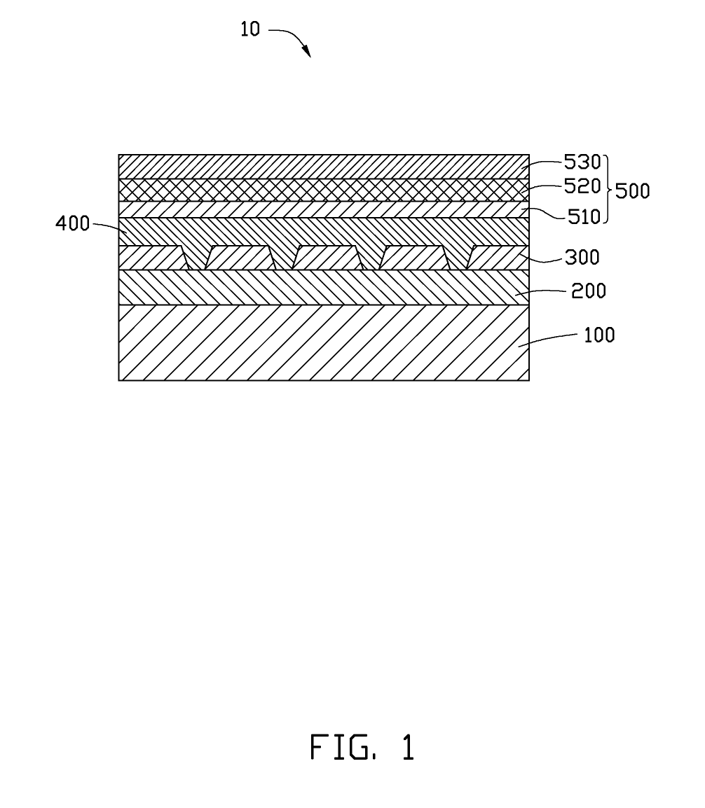

Referring to FIG. 1, a light emitting diode 10 includes a substrate 100, a buffer layer 200 on the substrate 100, a patterned layer 300 having a first refractive index on the buffer layer 200, a semiconductor layer 400 having a second refractive index, and an illumination structure 500 on the semiconductor layer 400, wherein the first refractive index is less than the second refractive index.

The substrate 100 can be sapphire, silicon carbon, or silicon material. In the present embodiment, the sapphire is applied as the substrate 100.

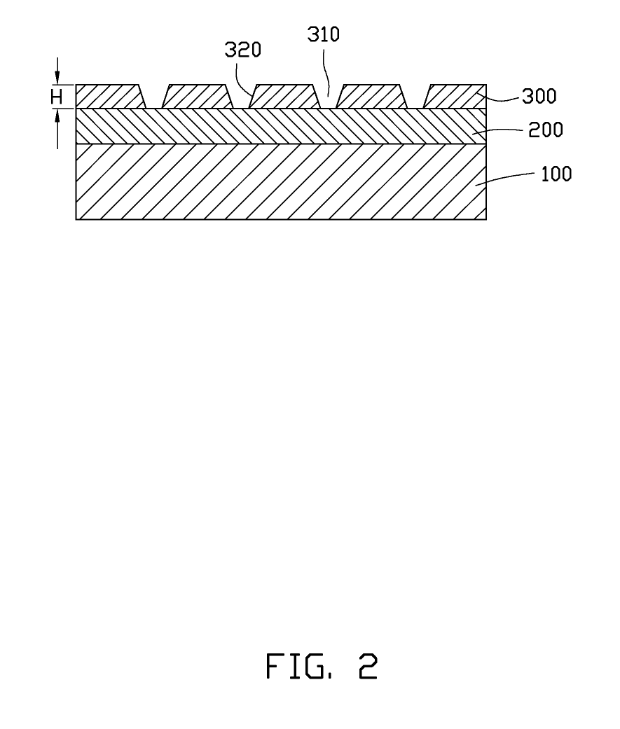

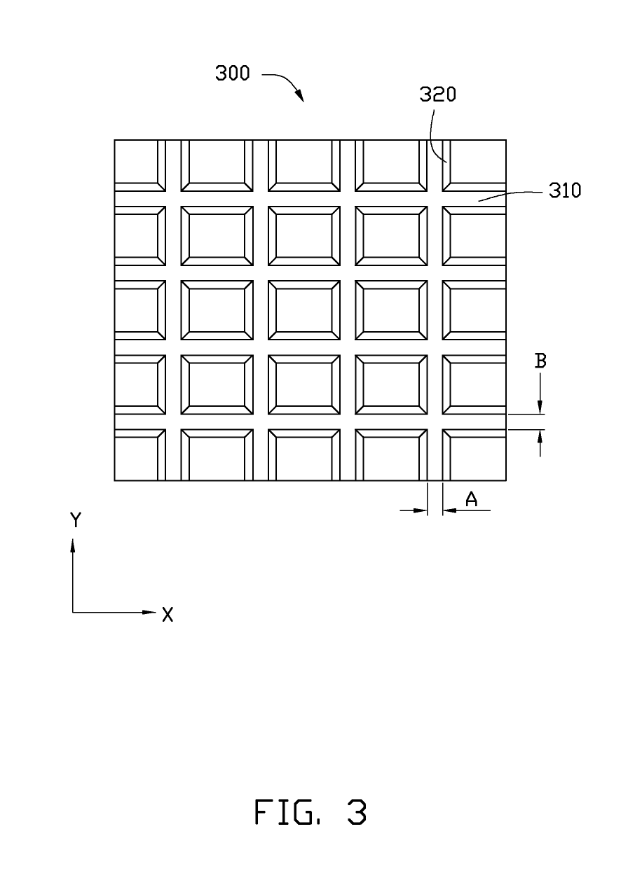

Referring to FIG. 2 and FIG. 3, the buffer layer 200 can be gallium nitride (GaN). The buffer layer 200 is grown on the substrate 100 at temperatures lower than those normally associated with epitaxy.

The patterned layer 300 can be aluminum nitride (AlN) with continuous grooves, partially continuous grooves, or other shaped grooves as a pattern. The continuous grooves can be a grid among multiple cylinders or polygonal columns. The partially continuous grooves can be parallel longitudinal grooves. In the present embodiment, the patterned layer 300 establishes x-coordinate and y-coordinate first, and then a plurality of grooves 310 is formed along the x-coordinate and the y-coordinate to form the pattern. The width of each of the plurality of grooves 310 along x-coordinate is represented by A, where 1 μm<A<5 μm, the width of each of the plurality of grooves 310 along y-coordinate is represented by B, where 1 μm<B<5 μm, and the thickness of the patterned layer is represented by H, where 0.05 μm<H<1 μm. Additionally, the plurality of grooves includes inclined sidewalls 320 for reflecting emitted light.

The semiconductor layer 400 can be aluminum gallium nitride (AlₓGa₁₋ₓN, where 0≦x≦1), which is grown on the patterned layer 300.

As mentioned, the illumination structure 500 includes an N type gallium nitride layer 510 on the semiconductor layer 400, a gallium nitride illumination layer 520 on the N type gallium nitride layer 510, a P type gallium nitride layer 530 on the gallium nitride illumination layer 520, wherein the gallium nitride illumination layer 520 can be a single hetero-structure layer, a double hetero-structure layer, a single quantum well layer, or a multiple quantum well layer.

In the process of manufacturing the light emitting diode 10, the plurality of grooves 310 of the patterned layer 300 can release the stress from the semiconductor layer 400 so as to reduce cracking on the surface of the semiconductor layer 400, and increase the epitaxial quality of illumination structure 500. Additionally, the refractive index of the semiconductor layer 400 is greater than the refractive index of the patterned layer 300. For this reason, when light emitted from the gallium nitride illumination layer 520 to the buffer layer 200 passes through the semiconductor layer 400 and the patterned layer 300, the light is totally reflected by an interface therebetween, and light extraction efficiency of the light emitting diode is maximized.

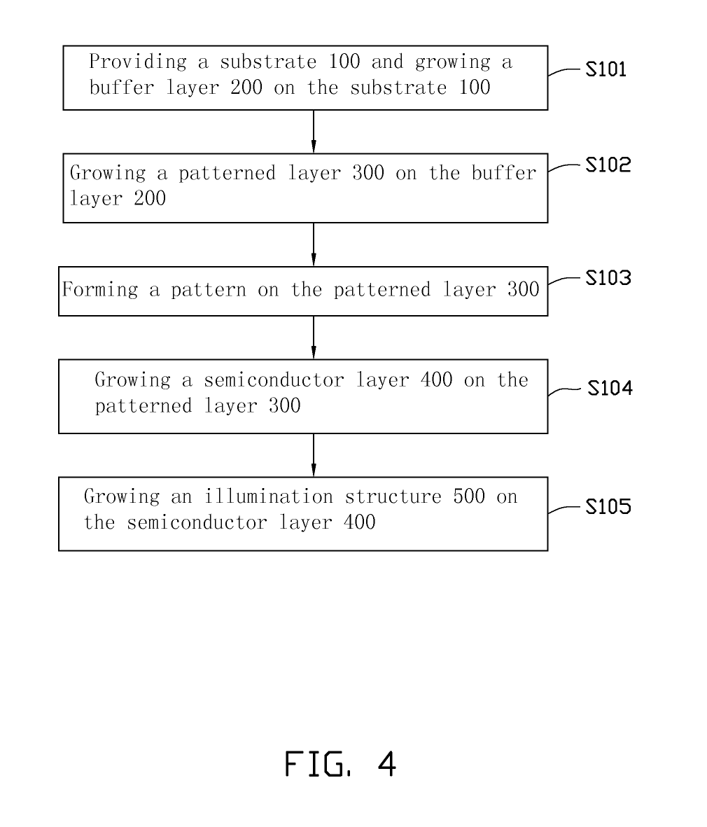

The present embodiment also provides a flow chart for manufacturing the light emitting diode as FIG. 4, comprising steps:

In step S101, a substrate 100 is provided and a buffer layer 200 is grown on the substrate 100, wherein the substrate 100 can be sapphire, silicon, or silicon material, and the buffer layer 200 can be gallium nitride (GaN).

In step S102, a patterned layer 300 is grown on the buffer layer 200, wherein the patterned layer 300 can be aluminum nitride (GaN).

In step S103, a pattern is formed on the patterned layer 300 by photolithography and etching, wherein the etching includes wet etching and dry etching. In the present embodiment, the patterned layer 300 establishes x-coordinate and y-coordinate first, and then the plurality of grooves 310 is formed therealong.

In step S104, a semiconductor layer 400 is grown on the patterned layer 300, wherein the patterned layer 300 can be aluminum gallium nitride (AlGaN).

In step S105, an illumination structure 500 is grown on the semiconductor layer 400, wherein the illumination structure 500 includes an N type gallium nitride layer 510 grown on the semiconductor layer 400, a gallium nitride illumination layer 520 grown on the N type gallium nitride layer 510, and a P type gallium nitride layer 530 grown on the gallium nitride illumination layer 520.

As mentioned, the buffer layer 200, the patterned layer 300, the semiconductor layer 500, and the illumination structure 500 are grown by metal organic chemical vapor deposition process or molecule beam epitaxy process.

The present disclosure has a patterned layer grown on the buffer layer, relieving stress from the semiconductor layer and avoiding cracking generated thereon, and enhancing the epitaxial quality of illumination structure. Furthermore, the refractive index of the semiconductor layer is greater than the refractive index of the patterned layer, such that light emitted from the illumination structure is fully reflected by an interface therebetween, reducing light absorbed by the substrate and enhancing light extraction efficiency of the light emitting diode. The present disclosure can further be applied to UV light emitting diodes.

What is claimed is:

1. A light emitting diode comprising:
a substrate;
a buffer layer on the substrate;
a patterned layer having a first refractive index on the buffer;
a semiconductor layer having a second refractive index on the patterned layer; and
an illumination structure on the semiconductor layer, wherein the first refractive index is less than the second refractive index.

2. The light emitting diode as claimed in claim 1, wherein the illumination structure includes an N type gallium nitride layer on the semiconductor layer, a gallium nitride illumination layer on the N type gallium nitride layer, and a P type gallium nitride layer on the gallium nitride illumination layer.

3. The light emitting diode as claimed in claim 1, wherein the substrate is sapphire, silicon carbon, or silicon material, the buffer layer is gallium nitride layer, the patterned layer having the first refractive index is aluminum nitride layer, and the semiconductor layer having the second refractive index is AlₓGa₁₋ₓN, where 0≦x≦1.

4. The light emitting diode as claimed in claim 1, wherein the patterned layer can be continuous grooves, partially continuous grooves or other shaped grooves.

5. The light emitting diode as claimed in claim 1, wherein the thickness of patterned layer is around 0.05 μm-1.0 μm.

6. The light emitting diode as claimed in claim 1, wherein the patterned layer has a plurality of grooves, and the width of each of grooves is around 1.0 μm-5.0 μm.

7. The light emitting diode as claimed in claim 6, wherein the groove has inclined sidewalls applied for reflection.

8. A manufacturing method of light emitting diode comprising:
providing a substrate;
growing a buffer layer on the substrate;
growing a patterned layer on the buffer layer;
growing a semiconductor layer on the patterned layer; and
growing an illumination structure on the semiconductor layer.

9. The manufacturing method of light emitting diode as claimed in claim 8, wherein the patterned layer has a plurality of grooves.
